(19) United States
(12) Patent Application Publication
(10) Pub. No.: US 2026/0354084 A1
(43) Pub. Date: Nov. 5, 2026

(54) SUBSTRATE SUPPORT PEDESTAL HAVING PLASMA CONFINEMENT FEATURES

(71) Applicant: Applied Materials, Inc., Santa Clara, CA (US)

(72) Inventors: Xing LIN, San Jose, CA (US); Vijay D. PARKHE, San Jose, CA (US); Jianhua ZHOU, Campbell, CA (US); Edward P. HAMMOND, IV, Hillsborough, CA (US); Jaeyong CHO, San Jose, CA (US); Zheng John YE, Santa Clara, CA (US); Zonghui SU, San Jose, CA (US); Juan Carlos ROCHA-ALVAREZ, San Carlos, CA (US)

(21) Appl. No.: 19/655,482

(22) Filed: Apr. 22, 2026

Related U.S. Application Data
(63) Continuation of application No. 17/332,458, filed on May 27, 2021, now abandoned.
Application No. 17/332,458 is a division of application No. 15/416,295, filed on Jan. 26, 2017, now abandoned.
(60) Provisional application No. 62/326,588, filed on Apr. 22, 2016.

(51) Int. Cl. H10P 72/00; C23C 14/50; C23C 16/458; C23C 16/46; C23C 16/509; H01J 37/32; H10P 72/76

(52) U.S. Cl. CPC H10P 72/0432; C23C 14/50; C23C 16/4586; C23C 16/46; C23C 16/5096; H01J 37/32082; H01J 37/32577; H01J 37/32715; H01J 37/32724; H10P 72/7626

(57) ABSTRACT

A method and apparatus for a heated substrate support pedestal is provided. In one embodiment, a substrate support pedestal includes a ceramic body having a top surface and a bottom surface. The substrate support pedestal has a stem coupled to the bottom surface of the ceramic body. A top electrode is disposed within the ceramic body. A conductive rod is disposed through the stem and coupled to the top electrode. A plurality of heater elements is disposed within the ceramic body below the top electrode. A ground mesh is disposed within the ceramic body, below the plurality of heater elements, and above the bottom surface of the ceramic body.

### CROSS-REFERENCE TO RELATED APPLICATIONS

This application is a continuation of U.S. Non-Provisional application Ser. No. 17/332,458 filed May 27, 2021 (Attorney Docket No. APPM/023997USD01), which is a divisional of U.S. Non-Provisional application Ser. No. 15/416,295, filed Jan. 26, 2017, (Attorney Docket No. APPM/023997US), which claims benefit of U.S. Provisional Application Ser. No. 62/326,588, filed Apr. 22, 2016 (Atty. Docket No. APPM/023997USL), each of which is incorporated by reference in its entirety.

### BACKGROUND

### Field

Embodiments disclosed herein generally relate to a substrate support pedestal having plasma confinement features.

### Description of the Related Art

Semiconductor processing involves a number of different chemical and physical processes enabling minute integrated circuits to be created on a substrate. Layers of materials which make up the integrated circuit are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or other appropriate material.

In the manufacture of integrated circuits, plasma processes are often used for deposition or etching of various material layers. Plasma processing offers many advantages over thermal processing. For example, plasma enhanced chemical vapor deposition (PECVD) allows deposition processes to be performed at lower temperatures and at higher deposition rates than achievable in analogous thermal processes. Thus, PECVD is advantageous for integrated circuit fabrication with stringent thermal budgets, such as for very large scale or ultra-large scale integrated circuit (VLSI or ULSI) device fabrication.

The processing chambers used in these processes typically include a substrate support or pedestal disposed therein to support the substrate during processing and a showerhead having a faceplate for introducing process gas into the processing chamber. The plasma is generated by two RF electrodes, where the faceplate functions as the top electrode. In some processes, the pedestal may include an embedded heater and embedded metal mesh to serve as the bottom electrode. Process gas flows through showerhead and the plasma is generated between the two electrodes. In conventional systems, RF current flows from the showerhead top electrode to heater bottom electrode through the plasma. The RF current will pass a nickel RF rod in the pedestal, and return back in the inner chamber wall through the pedestal structure. A long RF path leads to RF power loss. More importantly however, the long nickel RF rod has high inductance, which results in a high bottom electrode potential which in term may promote bottom chamber light-up, i.e., parasitic plasma generation.

Therefore, there is a need for an improved RF return path in the plasma processing chamber.

### SUMMARY

A method and apparatus for a heated substrate support pedestal is provided. In one embodiment, a substrate support pedestal includes a ceramic body having a top surface and a bottom surface. The substrate support pedestal has a stem coupled to the bottom surface of the ceramic body. A top electrode is disposed within the ceramic body. A conductive rod is disposed through the stem and coupled to the top electrode. A plurality of heater elements is disposed within the ceramic body below the top electrode. A ground mesh is disposed within the ceramic body, below the plurality of heater elements, and above the bottom surface of the ceramic body.

In another embodiment, a semiconductor processing chamber is provided that includes a chamber body having sidewalls, a lid and a bottom. The sidewalls, lid and bottom define an interior processing environment. A showerhead assembly has a faceplate that provides a cathode to an RF source. A pedestal is disposed in the interior processing environment. The pedestal a stem, and a body having a ceramic material. The body has a top surface and a bottom surface coupled to the stem. A top electrode is encapsulated within the body disposed adjacent the top surface. A center electrode is disposed through the stem and coupled to the top electrode. A plurality of heater elements is encapsulated within the body and coupled to heater electrodes disposed through the stem. The plurality of heater elements is disposed below the top electrode. A bottom mesh is encapsulated within the body, the bottom mesh disposed below the plurality of heater elements. A plurality of transmission lines is coupled to the bottom mesh.

In yet another embodiment of instant disclosure, a semiconductor processing chamber is provided that includes a body having sidewalls, a lid and a bottom. The sidewalls, lid and bottom define an interior processing environment. A showerhead assembly has a faceplate. A pedestal is disposed in the interior processing environment. The pedestal has a stem and a body that includes a ceramic material. The body has a top surface and a bottom surface that is coupled to the stem. A top electrode is encapsulated within the body, and disposed adjacent the top surface. A center electrode is disposed through the stem and coupled to the top electrode. A plurality of heater elements is encapsulated within the body, and coupled to heater electrodes disposed through the stem. The plurality of heater elements is disposed below the top electrode. A bottom mesh is encapsulated within the body, and disposed below the plurality of heater elements. A plurality of transmission lines is disposed in the stem and coupled to the bottom mesh. Each transmission line of the plurality of transmission lines is disposed radially outward of the center electrode.

### BRIEF DESCRIPTION OF THE DRAWINGS

So that the manner in which the above-recited features of the present disclosure can be understood in detail, a more particular description, briefly summarized above, may be had by reference to embodiments, some of which are illustrated in the appended drawings. It is to be noted, however, that the appended drawings illustrate only typical embodiments and are therefore not to be considered limiting of its scope, for the embodiments disclosed herein may admit to other equally effective embodiments.

FIG. 1 is a partial cross sectional view of one embodiment of a plasma system.

FIG. 2 is a schematic top view of one embodiment for a multi-zone heater that may be utilized as the pedestal in the plasma system of FIG. 1.

FIG. 3 is a schematic side view of one embodiment for a ground that may be utilized in the pedestal in the plasma system of FIG. 1

FIG. 4A is a cross-sectional schematic for one embodiment of a multi-zone heater that may be used in the plasma system of FIG. 1.

FIG. 4B is a cross-sectional schematic for a second embodiment of a multi-zone heater that may be used in the plasma system of FIG. 1.

FIG. 5 is a cross-sectional schematic of one embodiment of the multi-zone heater having a shortened RF rod for a plasma system having a top RF feed.

FIG. 6 is a cross-sectional schematic of one embodiment of the multi-zone heater having a top RF feed path.

FIG. 7 is a cross-sectional schematic of one embodiment of the multi-zone heater having a bottom RF feed path.

FIGS. 8A-8D illustrate various embodiments for a top electrode multi-zone heater.

FIG. 9 is a cross-sectional schematic of one embodiment of the multi-zone heater having a bottom mesh RF path.

FIG. 10 is a cross-sectional schematic of yet another embodiment of the multi-zone heater having a second embodiment for the bottom mesh RF path.

FIG. 11 is a cross-sectional schematic of yet another embodiment of the multi-zone heater having a third embodiment for the bottom mesh RF path.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure are illustratively described below in reference to plasma chambers, although embodiments described herein may be utilized in other chamber types and in multiple processes. In one embodiment, the plasma chamber is utilized in a plasma enhanced chemical vapor deposition (PECVD) system. Although the exemplary embodiment includes two processing regions, it is contemplated that embodiments disclosed herein may be used to advantage in systems having a single processing region or more than two processing regions. It is also contemplated that embodiments disclosed herein may be utilized to advantage in other plasma chambers including physical vapor deposition (PVD) chambers, atomic layer deposition (ALD) chambers, etch chambers, among others.

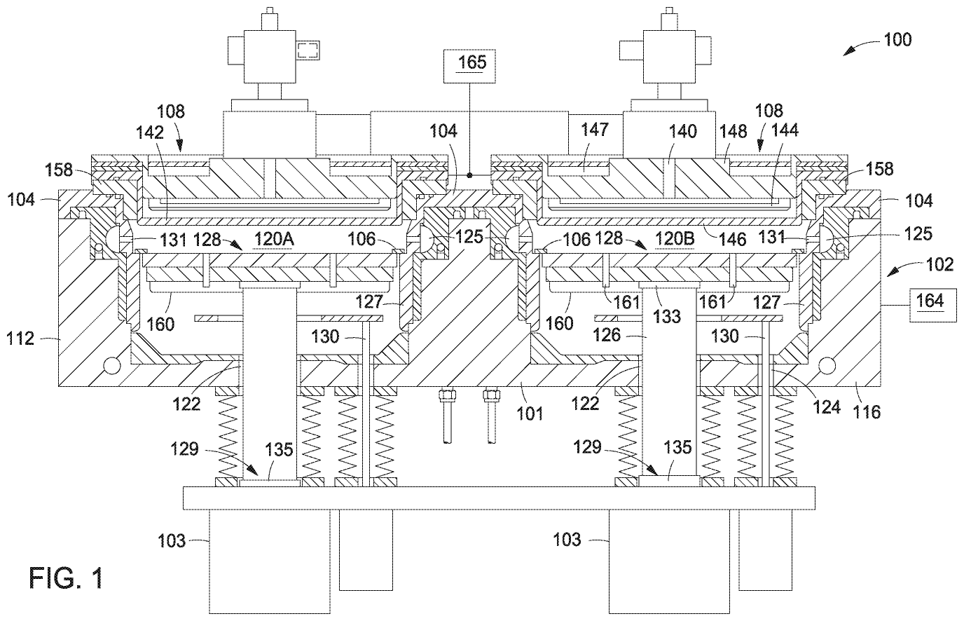

FIG. 1 is a partial cross sectional view of a processing chamber 100. The processing chamber 100 generally comprises a processing chamber body 102 having chamber sidewalls 112, a bottom wall 116 and a shared interior sidewall 101 defining a pair of processing regions 120A and 120B. Each of the processing regions 120A-B is similarly configured, and for the sake of brevity, only components in the processing region 120B will be described.

A pedestal 128 is disposed in the processing region 120B through a passage 122 formed in the bottom wall 116 in the processing chamber 100. The pedestal 128 provides a heater adapted to support a substrate (not shown) on the upper surface thereof. The pedestal 128 may include heating elements, for example resistive heating elements, to heat and control the substrate temperature to a desired process temperature. Alternatively, the pedestal 128 may be heated by a remote heating element, such as a lamp assembly.

The pedestal 128 is coupled by a flange 133 to a stem 126. The stem 126 couples the pedestal 128 to a power outlet or power box 103. The power box 103 may include a drive system that controls the elevation and movement of the pedestal 128 within the processing region 120B. The stem 126 also contains electrical power interfaces to provide electrical power to the pedestal 128. For example, the stem 126 may have electrical interfaces for providing power from the power box 103 to one or more heaters disposed in the pedestal 128. The stem 126 may also include a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 of the processing region 120B and is utilized to position substrate lift pins 161 disposed through the pedestal 128. The substrate lift pins 161 selectively space the substrate from the pedestal to facilitate exchange of the substrate with a robot (not shown) utilized for transferring the substrate into and out of the processing region 120B through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146.

A radio frequency (RF) source 165 is coupled to the showerhead assembly 142. This configuration is termed a top feed for the RF feed path. The faceplate 146 may act as a top electrode for the RF source 165. The RF source 165 powers the showerhead assembly 142 to facilitate generation of a plasma between the faceplate 146 of the showerhead assembly 142 and the heated pedestal 128. In one embodiment, the RF source 165 may be a high frequency radio frequency (HFRF) power source, such as a 13.56 MHz RF generator. In another embodiment, RF source 165 may include a HFRF power source and a low frequency radio frequency (LFRF) power source, such as a 300 kHz RF generator. Alternatively, the RF source may be coupled to other portions of the processing chamber body 102, such as the pedestal 128, to facilitate plasma generation.

A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120B in very close proximity to the chamber sidewalls 101, 112 of the chamber body 102 to prevent exposure of the chamber sidewalls 101, 112 to the processing environment within the processing region 120B. The liner assembly 127 includes a circumferential pumping cavity 125 that is coupled to a pumping system 164 configured to exhaust gases and byproducts from the processing region 120B and control the pressure within the processing region 120B. A plurality of exhaust ports 131 may be formed on the chamber liner assembly 127. The exhaust ports 131 are configured to allow the flow of gases from the processing region 120B to the circumferential pumping cavity 125 in a manner that promotes processing within the processing chamber 100.

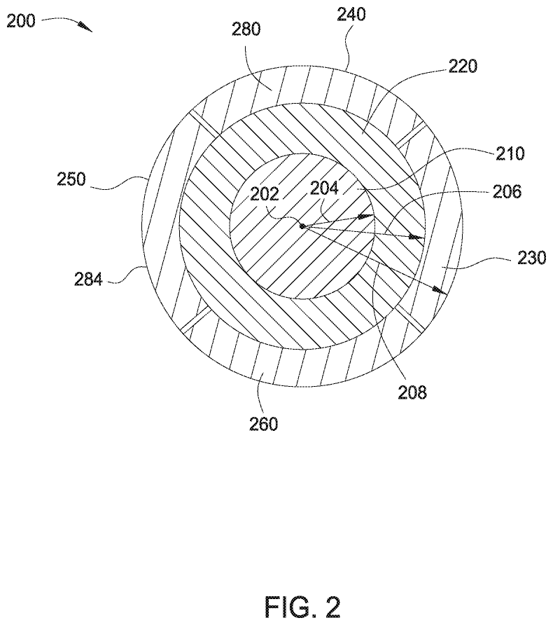

FIG. 2 is a schematic top view of one embodiment for a multi-zone heater (i.e., pedestal 200) that may be utilized as the pedestal 128 in the processing chamber 100 of FIG. 1. The pedestal 200 may have an outer perimeter 284 and a center 202. The pedestal 200 includes a plurality of zones that may be individually heated so that the temperature of each zone of the pedestal 200 may be independently controlled. In one embodiment, the pedestal 200 includes multiple heating zones which may be individually monitored for temperature metrics and/or adjusted, as needed, to obtain a desired temperature profile.

The number of zones formed in the pedestal 200 may vary as desired. In the embodiment depicted in FIG. 2, the pedestal 200 has six zones, such as an inner zone 210, an intermediate zone 220 and outer zone 280, the outer zone 280 further divided into four outer zones 230, 240, 250, 260. In one embodiment, each of the zones 210, 220 and 280 are concentric. As an example, the inner zone 210 may include an inner radius 204 from about 0 to about 85 millimeters (mm) extending from the center 202 of the pedestal 200. The intermediate zone 220 may include an inside radius, substantially similar to the inner radius 204 of the inner zone 210, such as about from 0 to about 85 millimeters. The intermediate zone 220 may extend from the inner radius 204 to an outer radius 206 of about 123 mm. The outer zone 280 may include an inner perimeter substantially the same as the outer radius 206 of the intermediate zone 220. The outer zone 280 may extend from the outer radius 206 to an outer perimeter radius 208 of about 150 mm or greater, such as about 170 mm, for example, about 165 mm.

While the outer zone 280 of the pedestal 200 is shown divided into four outer zones 230, 240, 250, 260, the number of zones may be greater or less than four. In one embodiment, pedestal 200 has four outer zones 230, 240, 250, 260. Thus, making pedestal 200 and six heater zone pedestal. The outer zones 230, 240, 250, 260 may be shaped as ring-segments, and be distributed around the inner zone 210 and intermediate zone 220. Each of the four outer zones 230, 240, 250, 260 may be substantially similar to each other in shape and size. Alternately, the shape size of each of the four outer zones 230, 240, 250, 260 may be configured to align with asymmetries in the processing environment of the chamber 100. Alternately, the four outer zones 230, 240, 250, 260 may be circular in shape and concentrically arranged from the intermediary zone 220 to the outer perimeter 284.

In order to control the temperature in each zone 210, 220, 230, 240, 250, 260 of the pedestal 200, each zone is associated with one or more independently controllable heaters. The independently controllable heaters are further discussed below.

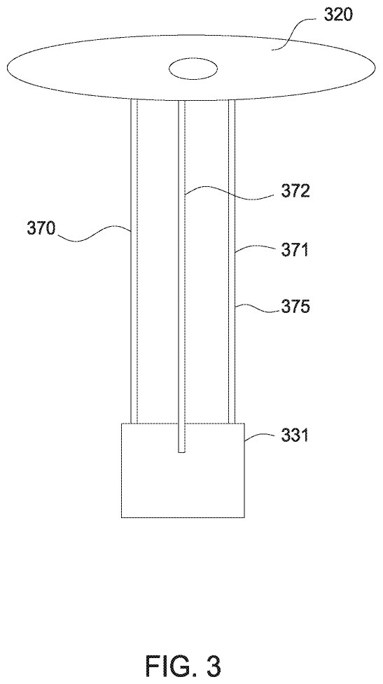

FIG. 3 is a schematic side view of one embodiment for a ground that may be utilized in the pedestal in the plasma system of FIG. 1. The ground may be suitable for containing RF energy or allowing the RF energy to pass therethrough. The ground may be in the form of a conductive plate, mesh or other suitable electrode, hereinafter referred to as ground mesh 320. The ground mesh 320 may be disposed in various locations within the pedestal 128, and several exemplary locations for the ground mesh 320 will be discussed with reference to the Figures below. The ground additionally has a ground block 331. The ground block 331 may be coupled to directly ground, or to ground through the RF match of the RF source 165. The ground block 331, ground mesh 320 may be formed from aluminum, molybdenum, tungsten, or other suitably conductive material.

The ground mesh 320 may be coupled to the ground block 331 by the ground tube 375. Alternately, the ground mesh 320 may have a plurality of transmission leads, such as a first transmission lead 370 and a second transmission lead 371 disposed between the ground block 331 and the ground mesh 320. The ground mesh 320 may include a passage for allowing a RF transmission rod 372 to pass through the ground mesh 320. The ground tube 375, the transmission leads 370, 371 and RF transmission rod 372 may be formed from aluminum, titanium, nickel or other suitably conductive material and electrically coupled the ground mesh 320 to the ground block 331. The ground tube 375 may be cylindrical in shape having an inner hollow portion in which chamber components can pass therethrough, such as RF anode, cathode, heater power, cooling lines, and the like. The transmission leads 370 may similarly be arranged in a manner that surround the aforementioned chamber components.

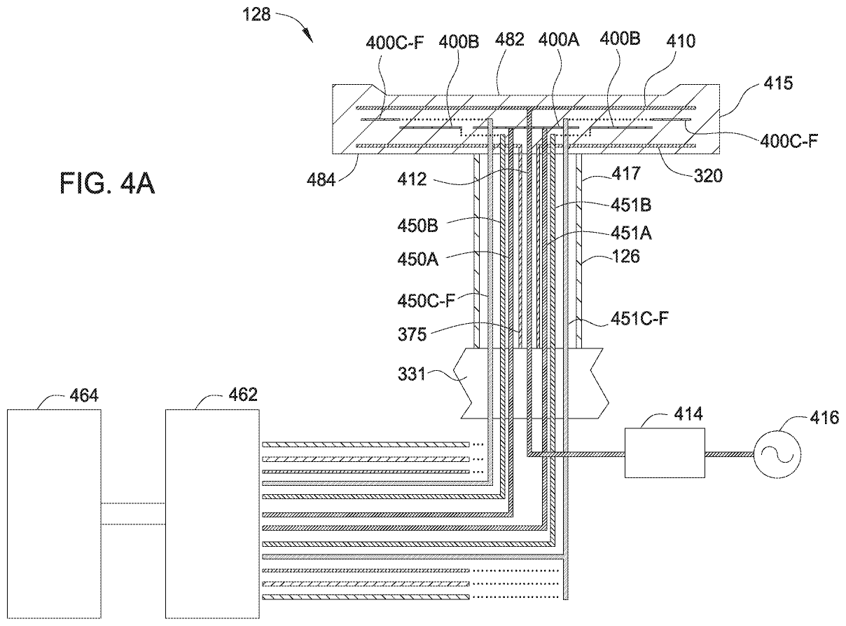

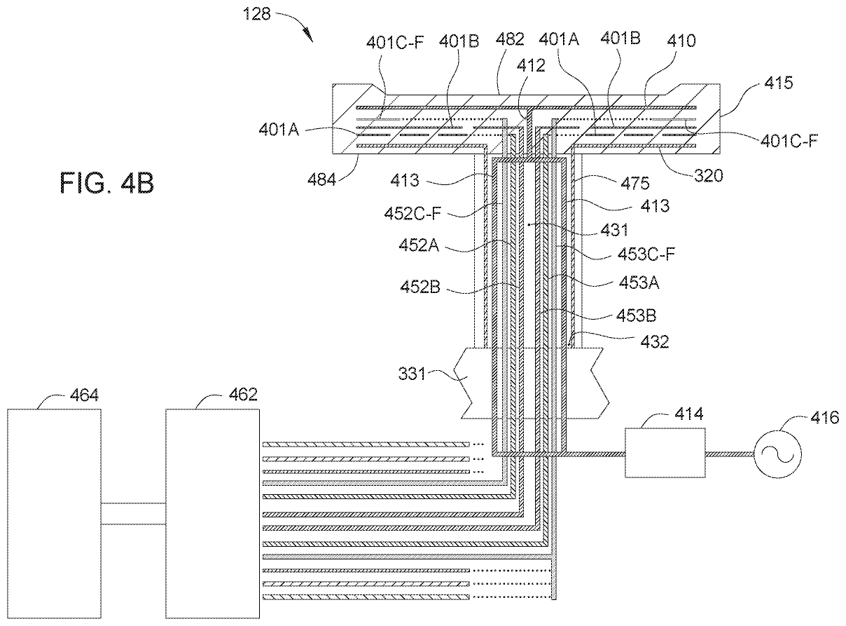

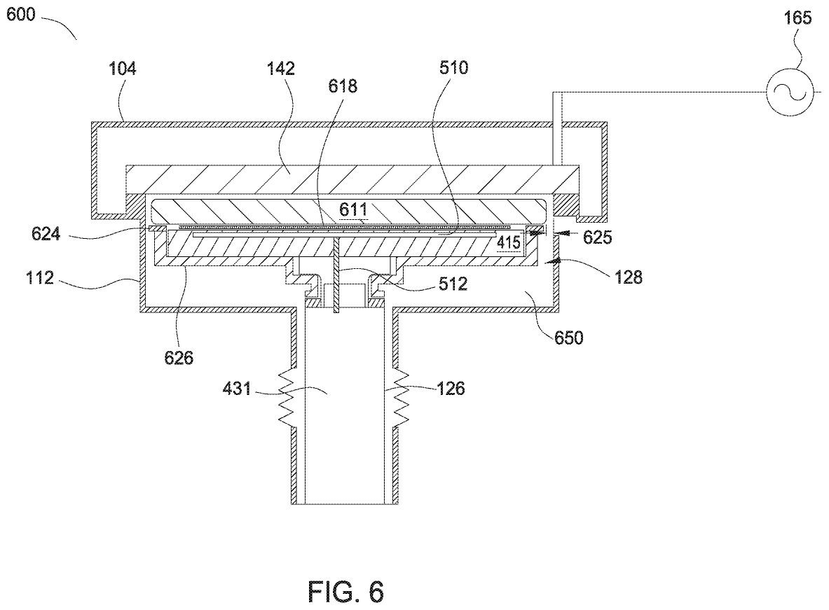

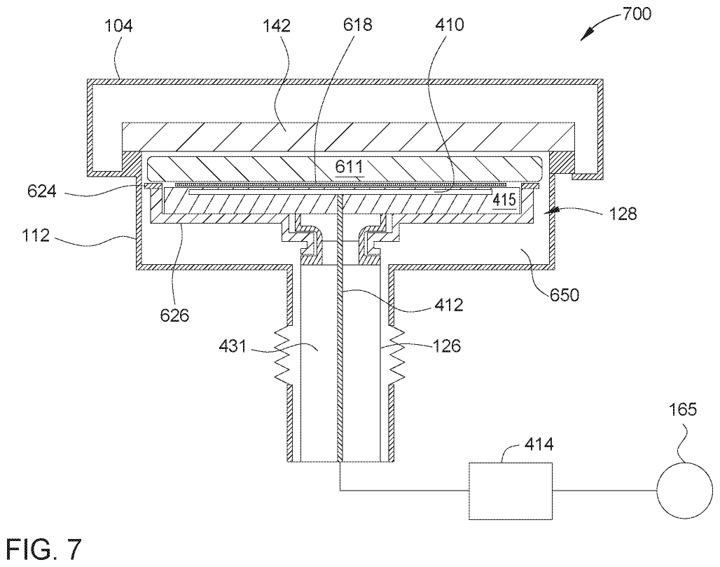

FIG. 4A is a cross-sectional schematic of a multi-zone heater, i.e., pedestal 128, according to one embodiment, which may be used in the plasma system of FIG. 1. The pedestal 128 illustrated in FIG. 4A has a bottom RF feed. However, it should be appreciated that the pedestal 128 can be easily reconfigured for a top RF feed and the differences between the top and bottom RF feed are illustrated in FIGS. 6 and 7. The pedestal 128 has a dielectric body 415. The dielectric body 415 may be formed from a ceramic material, such as AlN or other suitable ceramic. The dielectric body 415 has a top surface 482 configured to support a substrate thereon. The dielectric body 415 has a bottom surface 484 opposite the top surface 482. The pedestal 128 includes a stem 126 attached to the bottom surface 484 of the dielectric body 415. The stem 126 is configured as a tubular member, such as a hollow dielectric shaft 417. The stem 126 couples to the pedestal 128 to the processing chamber 100.

The pedestal 128 is configured as a multi-zone heater, having a central heater 400A, an intermediary heater 400B and one or more outer heaters, illustratively shown in FIG. 4A as 400C-F. The central heater 400A, intermediary heater 400B and outer heaters 400C-F may be utilized to provide multiple, independently controlled heating zones within the pedestal 128. For example, the pedestal 128 may include a central zone configured with the central heater 400A, an intermediary zone configured with the intermediary heater 400B and one or more outer zones configured with the outer heaters 400C-F, such that each heater is aligned with and defines the heating zones of the pedestal, for example such as the zones 210, 220, 230, 240, 250, 260 of the pedestal 200 shown in FIG. 2.

The dielectric body 415 may also include an electrode 410 therein for use in plasma generation in the adjacent processing region above the pedestal 128. The electrode 410 may be a conductive plate or a mesh material embedded in the dielectric body 415 of the pedestal 128. Likewise, each of the heaters 400A, 400B, 400C-F may be a wire or other electrical conductor embedded in the dielectric body 415 of the pedestal 128. The dielectric body 415 may additionally include the ground mesh 320. The ground mesh 320 may provide a ground shield for the heaters 400A-F.

Electrical leads, such as wires, for the heaters 400A, 400B, 400C-F, as well as the electrode 410 and the ground mesh 320, may be provided through the stem 126. Temperature monitoring devices (not shown), such as flexible thermocouples, may be routed through the stem 126 to the dielectric body 415 to monitor various zones of the pedestal 128. A power source 464 may be coupled to the electrical leads through a filter 462. The power source 464 may provide alternating current to the pedestal 128. The filter 462 may be a single frequency, such as about 13.56 MHz, or other suitable filter for filtering RF frequencies in the chamber 100 from the power source 464. The heaters 400A-F may be controlled with an optical communication to prevent RF power from traveling out through the optical connections and damaging equipment outside the chamber 100.

The ground mesh 320 functions to reduce or prevent parasitic plasma from forming below the bottom surface 484 of the pedestal 128. The ground tube 375 may also be configured to inhibit the parasitic plasma formation along the stem 126 of the pedestal 128. For example, the electrode 410 used in plasma generation may have a power lead 412 central to the stem 126. The RF power lead 412 extends through the ground block 331 of the chamber to a RF power source 416 through a match circuit 414. The power source 416 may provide direct current for driving the plasma. The ground mesh 320 provides a ground plate and isolates the power source 416 and electrode 410 from portions of the chamber 100 below the bottom surface 484 of the pedestal 128, thereby reducing the potential for plasma formation below the pedestal 128 which may cause unwanted deposition or damage to chamber components.

The RF power lead 412 is disposed between the ground tube 375 to prevent coupling to plasma adjacent the stem 126 of the pedestal 128. The electrical leads additionally include a plurality of heater power supply lines 450A-F and heater power return lines 451A-F. The heater power lines 450A-F provide power from the power source 464 for heating the pedestal 128 in one or more of the zones. For example, the heater power supply line 450A and heater power return line 451A, collectively heater transmission lines 450, 451, connect the central heater 400A to the power source 464. Likewise, the heater power supply lines 450B, 450C-F and heater power return lines 451B, 451C-F may provide power to intermediary heater 400B and outer heaters 400C-F from the power source 464. The transmission leads 370 or ground tube 375 may be disposed between the RF power lead 412, such as the rod 372 illustrated in FIG. 3, and both the heater power lines 450A-F. Thus, the heater power lines cathodes 450A-F may be isolated from the RF power lead 412

Many materials utilized to make advanced patterning films (APF) are very sensitive to the temperature profile of the substrate and deviations from a desired causes temperature profile may result in skewing and other uniformities of the properties and performance of deposited films. To enhance control of the temperature profile, the pedestal 128 may be configured with six or more heaters 400A-F, each heater associated and defining a respective heating zone of the pedestal 168, to provide a highly flexible and tunable temperature profile control for the top surface 482 of the pedestal 128, and thus, allows excellent control of process results across the substrate thereby controlling process skew. The ground mesh 320, along with the ground tube 375, provides a ground shield to screen the RF energy and confine the plasma above the plane of the substrate, substantially preventing parasitic plasma formation along the bottom surface 484 and adjacent the stem 126 of the pedestal 128.

FIG. 4B is a cross-sectional schematic of a multi-zone heater, i.e., pedestal 128, according to a second embodiment, which may be used in the plasma system of FIG. 1. The pedestal 128 is configured with a first zone heater 401A, a second zone heater 401B and a third zone heater 401C-F disposed in the dielectric body 415. The pedestal 128 additionally has an RF tube 413, disposed in the stem 126, electrically coupled to the electrode 310 in the dielectric body 415. The ground tube 375 and ground mesh 320 are also disposed in the pedestal 128. The heaters 401A-F may be optically controlled. A temperature probe (not shown) may also be disposed in the dielectric body 415 to provide feedback for controlling the heaters 401A-F.

The first zone heater 401A is configured to provide a heating source to the entire the top surface 482 of the pedestal 128. The first zone heater 401A may be operable to heat to pedestal from about or below room temperature to about 400° Celsius or more, such as 450° Celsius. The first zone heater 401A may be a resistive heater. The resistance of the first zone heater 401A may be temperature dependent and increase with an increase in the temperature. The first zone heater 401A may have a resistance greater than about 2 Ω (ohms), such as between about 6 Ω to about 7 Ω. The power source 464 is coupled through power leads 452A, 453A to energize the first zone heater 401A. For example, the power source 464 may provide 208 Volts to the resisters in the first zone heater 401A to generate heat.

The second zone heater 401B is spaced from the first zone heater 401A in the dielectric body 415. In one embodiment, the second zone heater 401B is spaced above the first zone heater 401A. The second zone heater 401B may be resistance heater and have a resistance greater than about 2 Ω (ohms), such as between about 5 Ω to about 6 Ω. The second zone heater 401B may extend from the through the dielectric body 415 in a manner such that the heat provided from the second zone heater 401B is transferred along the entire top surface 482 of the pedestal 128. The power source 464 is coupled through power leads 452B, 453B to energize the second zone heater 401B. The power source 464 may provide 208 Volts to the resisters in the second zone heater 401B to generate additional heat to raise the temperature of the dielectric body 415 above 450° Celsius such as 550° Celsius or greater. The second zone heater 401B may begin operation after the first zone heater 401A, or dielectric body 415 achieves a predetermined temperature. For example, the second zone heater 401B may turn on after the dielectric body 415 achieves a temperature greater than about 400° Celsius or more, such as 450° Celsius.

The third zone heater 401C-F is spaced from the second zone heater 401B in the dielectric body 415, such as above the first and second zone heaters 401A, 401B. The third zone heater 401C-F may be substantially similar to outer heaters 400C-F in FIG. 4A and configured to operate in the four outer zones 230, 240, 250, 260 of the dielectric body 415 depicted in FIG. 2. The third zone heater 401C-F may be resistance heaters and have a resistance greater than about 2 Ω (ohms), such as between about 5 Ω to about 6 Ω. The third zone heater 401C-F operate on the perimeter of the dielectric body 415 and may tune the temperature profile of the top surface 482 of the pedestal 128. The power source 464 is coupled through power leads 452C-F, 453C-F to energize the second zone heater 401B. The power source 464 may provide 208 Volts to the resisters in the third zone heater 401C-F to generate additional heat to adjust the temperature profile of the top surface 482 of the dielectric body 415. The operation of the heaters 401A-F advantageously utilizes less power to heat the top surface 482 of the pedestal.

The RF power lead 412, coupled to the electrode 310, is shortened and does not extend through the stem 126. The RF tube 413 is coupled to the RF power lead 412. For example, the RF tube 413 may be coupled to the RF power lead 412 by brazing, welding, crimping, and 3D printing or through other suitably conductive techniques. The RF tube 413 may be formed from aluminum, stainless steel, nickel or other suitably conductive material and electrically coupling the electrode 310 to the RF power source 416.

The RF tube 413 may be cylindrical in shape. The RF tube 413 has an inner area 431 and an outer area 432. Chamber components, power leads 452A-F, 453A-F and the like, can pass through the inner area 431 of the RF tube 413 with minimal RF energy transfer from the RF tube 413 to the chamber components. The outer area 431 of the RF tube 413 may be bounded by the ground tube 475. The RF tube 413 disposed about the power leads 452A-F, 453A-F prevents the heaters 401A-F and their respective power leads 452A-F, 453A-F from becoming an RF antennae. The ground tube 475 prevents RF energy from the RF tube 413 from igniting plasma outside the pedestal adjacent to the stem. Advantageously, the RF tube 413 provides a short transmission path for the RF energy with minimal parasitic power loss while preventing the heaters from becoming an RF antennae and igniting plasma adjacent the pedestal 128.

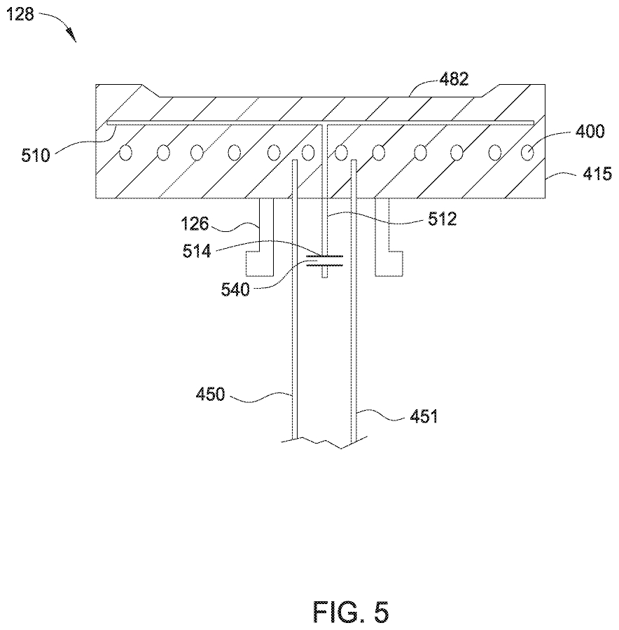

FIG. 5 is a cross-sectional schematic of one embodiment of the multi-zone heater pedestal 128, illustrated in FIGS. 2 and 4, having an RF rod 512 shorter then used in conventional systems. The RF rod 512 may be formed from nickel or other suitably conductive material. The RF rod 512 has an end 514. An optional capacitor 540 may be disposed proximate or at the end 514 of the RF rod 512. The capacitor 540 may alternatively be located in a different location. The capacitor 540 functions to effectively generate a resonance with the heater inductance to minimize the potential at the substrate, and thus form the virtual ground for reducing bottom parasitic plasma.

The RF current flows through the plasma from the showerhead top electrode, i.e., the faceplate 146 in FIG. 1, to electrode 510 disposed in the pedestal 128. The RF current will pass from the electrode 510 to the RF rod 512. The RF rod 512 transmits the RF energy back to the RF anode, i.e., chamber sidewall 112, liner assembly 127, or ground. The RF energy may pass from the RF rod 512 through the pedestal bellows, ground straps, or other conductive pathway to the RF anode. It is a long RF path leading to RF power loss, transmission line loss associated with different RF frequencies. A long conventional RF rod forms a high inductor in high frequency RF plasma, which results in a high bottom electrode potential leading to a bottom chamber light-up and parasitic plasma generation. The RF rod 512 is shortened compared to the longer conventional RF rods. For example, the RF rod 512 may be shortened to between about ½ to about ⅓ the length of conventional RF rods. For example, the RF rod 512 may have a length between about 2 inches and about 5 inches, such as about 2.85 inches. The effect of shortening the RF rod 512 is that the impedance of RF rod 512 is reduced dramatically from conventional RF rods. For example, the impedance of the RF rod 512 may be about 3 ohms (Ω) to about 7.5 Ω such as about 4.5 Ω. The potential of ground mesh 320 can be controlled to have a very low potential, which creates a virtual ground for the bottom of the chamber 100. The stem 126 may additionally be cooled to allow vacuum sealing by an O-ring during high temperature applications.

FIG. 6 is a cross-sectional schematic of one embodiment of the multi-zone heater having a top RF feed path. The chamber 600 illustrates a top RF feed path. The showerhead assembly 142 is hot, i.e., the cathode, and the electrode 510 is the ground, i.e., anode, in the RF circuit. The pedestal 128 is provided in a processing chamber 600. The processing chamber 600 may be substantially similar in use and configuration, or even identical, to chamber 100. The pedestal 128 is provided with a ground cover 626. The pedestal 128 may optionally have a plasma screen 624. In embodiments where there is a plasma screen 624, a gap 625 may form between the plasma screen 624 and the chamber sidewall 112. A plasma 611 may be confined above a substrate 618 disposed on the pedestal 128 for processing the substrate 618.

The plasma screen 624 has openings or holes allowing process gas delivery while providing RF ground path flow to prevent plasma penetration to the bottom chamber environment 650. As a result, the plasma 611 is confined to the top of the substrate 618 and improves film deposition above the level of the substrate 618. The plasma screen 624 may be formed materials similar to the ground cover 626 discussed below, such as Al, to provide conductivity. The plasma screen 624 may be electrically coupled to the chamber anode, such as the ground cover 626 or chamber sidewall 112. The plasma screen 624 may be electrically coupled to the chamber sidewall 112 with grounding straps or by other suitable techniques such as minimizing the gap 625 to about zero. In one embodiment, the plasma screen is about 10 mils from the chamber sidewall 112. In another embodiment, the plasma screen 624 touches the chamber sidewall 112, i.e., the gap is 0.0 mils.

The ground cover 626 optimizes the returned RF flow by creating a short RF flow path. The ground cover 626 shields the embedded RF electrode 510 from a bottom chamber environment 650 of the processing chamber 600. The ground cover 626 is a conductive shield which covers the ceramic heater, i.e., pedestal 128. The ground cover 626 may be formed stainless steel, aluminum, a conductive ceramic like silicon carbide (SiC) or other conductive material suitable for high temperatures. This ground cover 626 serves as the RF ground with a RF return loop. The ground cover 626 may additionally be connected to the plasma screen 624 forming a beneficially short RF flow path compared to being routed through the pedestal and bottom of the processing chamber.

The ground cover 626 may be formed from a thick Al layer suitable for use in high temperature environments. Additionally, the ground cover 626 may optionally have coolant channels (not shown) embedded therein. Alternately, the ground cover 626 may be formed from silicon carbide (SiC), a very conductive ceramic, suitable for use in very high temperatures. In some embodiments, the surface of ground cover 626 may be coated with a high fluorine corrosion resistant material like yttrium aluminum garnet (YAG), aluminum oxide/silicon/magnesium/yttrium (AsMy), and the like. The ground cover 626 may touch the pedestal 128 or have a small gap therebetween, such as about 5 mils to about 30 mils. Maintaining a substantially small gap between the ground cover 626 and the pedestal 128 prevents plasma generation inside the gap. In one embodiment, the whole bottom heater surface is coated with a metal layer such as nickel. Advantageously, the ground cover 626 provides a short RF return path and substantially eliminates both bottom and side parasitic plasma. The plasma screen 624 used in conjunction with the ground cover 626 shortens the RF return path further and confines the plasma above pedestal 128.

FIG. 7 is a cross-sectional schematic of one embodiment of the multi-zone heater having a bottom RF feed path. The chamber 700 is substantially similar to chamber 600 except for the RF feed location. The chamber 700 illustrates a bottom RF feed path. The electrode 410, in the pedestal 128, is coupled by the power lead 412 through the match circuits 414 to the RF power source 416. The electrode 410 provides RF energy to the plasma 611 for maintaining the plasma 611. An RF circuit is formed from the cathode at the electrode 410 through the plasma 611 to the anode at the showerhead assembly 142. The showerhead assembly 142 is the ground, i.e., anode, and the electrode 410 is RF hot, i.e., the cathode, in the RF circuit. The RF circuit of FIG. 7 is reverse of that disclosed in FIG. 6.

The pedestal 128 may otherwise be similarly configured with the ground cover 626 and the plasma screen 624. The plasma screen 624 maintains the plasma above the pedestal 128. The ground cover 626 prevents RF energy from the power lead 412 and electrode 410 from igniting the gas adjacent the stem 126 and forming parasitic plasma. FIGS. 6 and 7 illustrates embodiments that advantageously inhibit the formation of parasitic plasma in a cost effective manner which does not involve adding, i.e., changing, grounding in the dielectric body 415 of the pedestal 128.

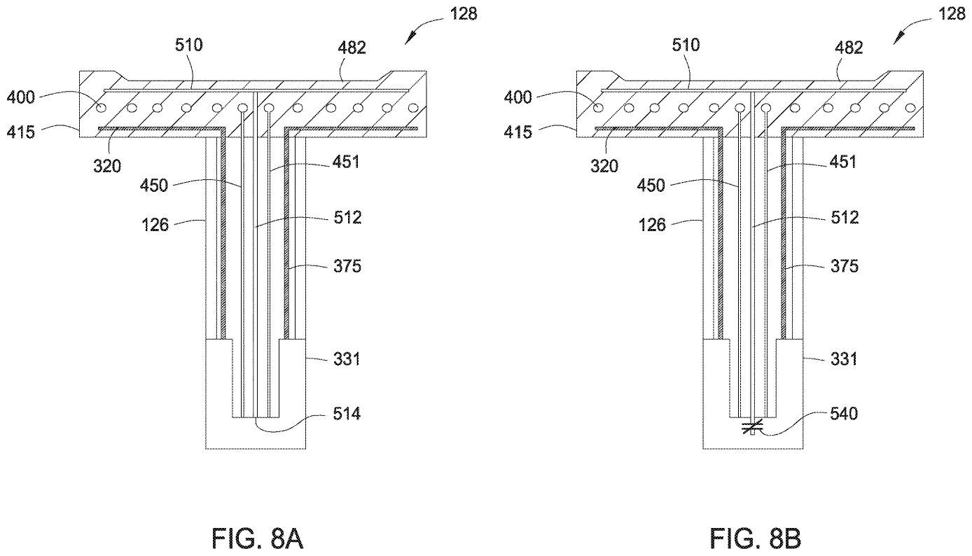

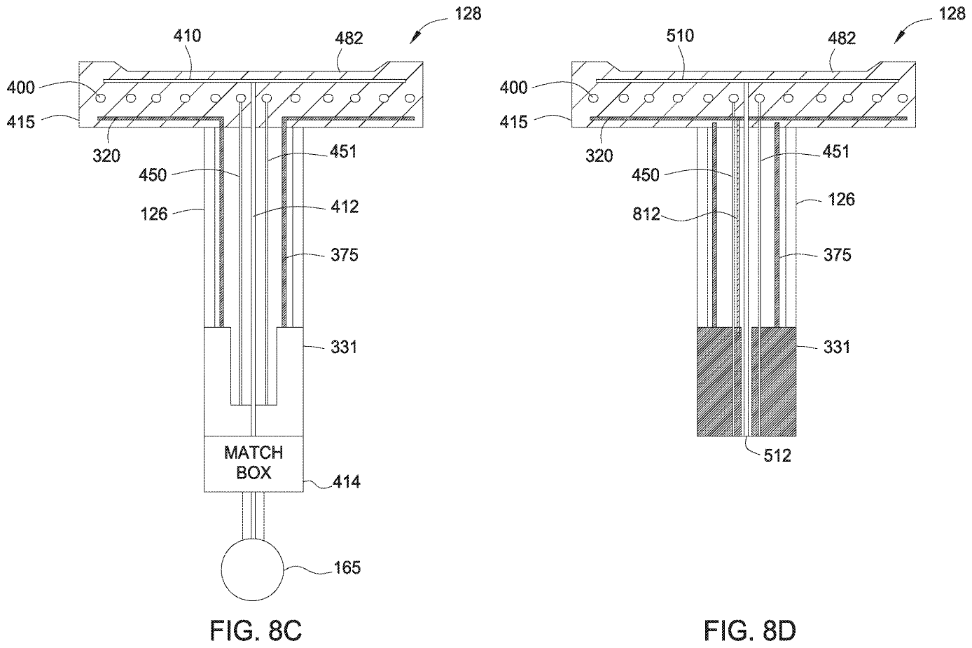

FIGS. 8A-8D illustrate various embodiments for a top electrode multi-zone heater pedestal. FIG. 8A illustrates a top driven RF circuit having the electrode 510 embedded in the pedestal 128A. The electrode 510 is directly coupled to the ground block 331 by the ground rod 512. FIG. 8B illustrates a top driven RF circuit having the electrode 510 embedded in the pedestal 128B. The electrode 510 is coupled to the ground rod 512 which has the capacitor 540 for varying the impedance. Other circuit elements, such as an inductor, may be deposed between the electrode 510 and ground for controlling the impedance to tune the performance of the electrode 510. FIG. 8C illustrates a bottom driven RF circuit having the electrode 410 embedded in the pedestal 128C. FIG. 8D illustrates a top driven RF circuit having the electrode 510 embedded in the pedestal 128D. The electrode 510 has a rod 512 which passes through the ground block 331. The second RF grounding mesh 320 is embedded in the pedestal 128D. A terminal may be brazed into the second RF grounding mesh 320. A hollow sleeve 812 disposed in the stem 126 may connected to the second RF grounding mesh 320. The sleeve 812 may be formed from aluminum (Al), or other suitable conductive material. The sleeve 812 surrounds RF rod 512, and thus will shield E field in high voltage RF applications. In this manner, the parasitic plasma can be substantially prevented from forming around the stem 126. Additionally, the ground tube 375 extends from the ground block 332 without connection to the grounding mesh 320. This configuration allows the grounding along the stem 126 to be further isolated from RF energy coupled to either the rod 512 or the heater transmission lines 450, 451.

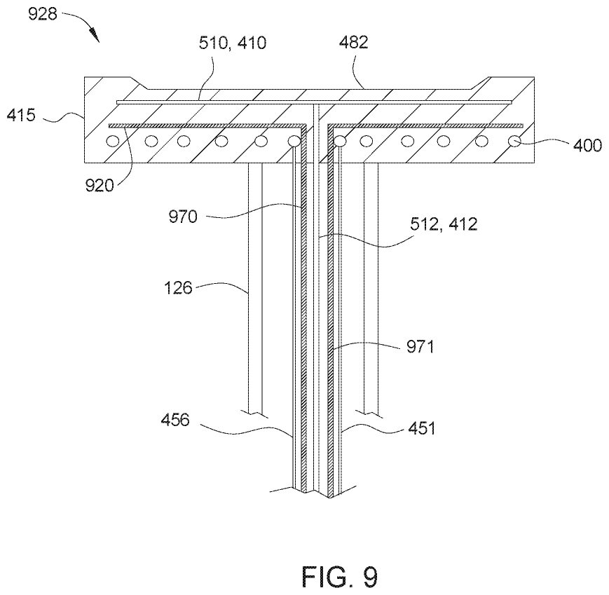

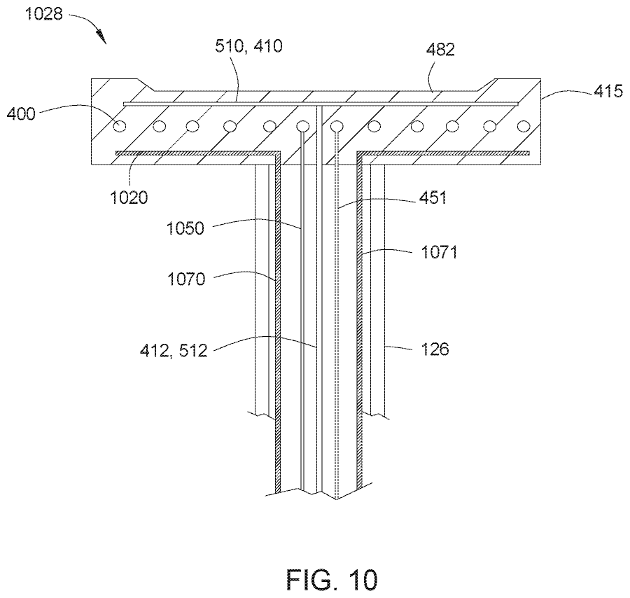

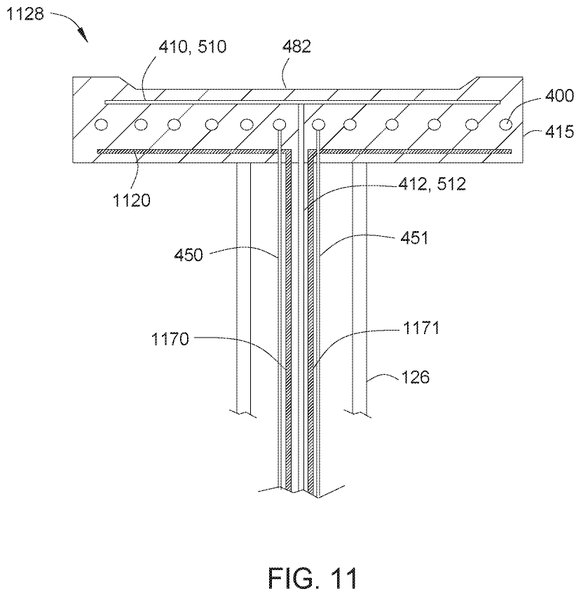

The benefits and operations of pedestals 128A-128D may be further discussed in relation to the configurations for shielding disclosed in FIGS. 9 through 11. FIG. 9 is a cross-sectional schematic of one embodiment of the multi-zone heater having a bottom mesh RF path. FIG. 10 is a cross-sectional schematic of yet another embodiment of the multi-zone heater having a second embodiment for the bottom mesh RF path. FIG. 11 is a cross-sectional schematic of yet another embodiment of the multi-zone heater having a third embodiment for the bottom mesh RF path. FIG. 9 through FIG. 11 illustrate pedestals 928, 1028, 1128, i.e., heaters, containing alternate embodiments for the RF transmission line structure and bottom shield provided by a ground mesh 320. The pedestals 928, 1028, 1128 have a plurality of heaters 400 and additionally are equipped with the electrode 410. In one embodiment, the heaters 400 are configured for 9 zones of heating as illustrated in FIGS. 2 and 4. However, it should be appreciated that the configurations for the heaters 400 can have one heating element, two heating element or multi-heating elements. These configurations lead to a single zone heater, dual zone heater, and multi-zone heaters allowing highly flexible temperature control. Furthermore, the pedestals 928, 1028, 1128 are illustrated in a manner wherein the RF may be top driven or bottom driven. Therefore, although the discussion of the embodiments are towards a bottom driven RF, the embodiments disclosed in FIGS. 9-11 are equally suitable for both top or bottom driven RF plasma systems.

The following discussion is to a pedestal 928 shown in FIG. 9. Pedestal 928 has a second layer of metal mesh 920. The metal mesh 920 is disposed between the heaters 400 and the electrode 410 in the dielectric body 415 of the pedestal 928. The metal mesh 920 has transmission lines 970, 971. The transmission lines 970, 971 may be a metal sleeve, such as a conductive cylinder, connected to the metal mesh 920. The transmission lines 970, 971 are disposed between RF power lead 412 and the heater anode 451 and cathode 450. The metal sleeve, i.e., transmission lines 970, 971, may surround the RF power lead 412. Above the metal mesh 920, the electrode 410, a first layer of metal mesh, functions as the RF hot. This dual layer of RF mesh (metal mesh 920 and electrode 410) forms a transmission line structure for the RF signal. The length of the transmission line can be used to adjust the voltage standing wave ratio (VSWR) and/or the potential at the substrate. The transmission lines 970, 971 serve as a RF grounding shield to advantageously control parasitic plasma formation adjacent the stem 126.

The following discussion is to a pedestal 1028 shown in FIG. 10. Pedestal 1028 has a second layer of metal mesh 1020. The metal mesh 1020 has transmission lines 1070, 1071. The metal mesh 1020 is disposed below both the heaters 400 and the electrode 410 in the dielectric body 415 of the pedestal 1028. This metal mesh 1020 may be sintered in the bottom of dielectric body 415. The transmission lines 1070, 1071 may be a metal sleeve, such as a conductive cylinder, connected to the metal mesh 1020. The transmission lines 1070, 1071 are disposed outside both RF power lead 412 and the heater anode 451 and cathode 450, i.e., heater transmission lines. The metal sleeve, i.e., transmission lines 1070, 1071, may surround both the RF power lead 412 and the heater anode 451 and cathode 450. Thus, RF energy from the RF power lead 412 and the electrode 410 is contained by both the metal mesh 1020 and the transmission lines 1070, 1071. Additionally, any coupling of the RF energy to the heater anode 451 and cathode 450, as well as the heaters 400, is contained the metal mesh 1020 and the transmission lines 1070, 1071. This configuration allows the length of the transmission line can be used to adjust the voltage standing wave ratio and/or the potential at the substrate while preventing parasitic plasma.

The following discussion is to a pedestal 1128 shown in FIG. 11. Pedestal 1128 has a second layer of metal mesh 1120. The metal mesh 1120 has transmission lines 1170, 1171. The metal mesh 1120 is disposed below both the heaters 400 and the electrode 410 in the dielectric body 415 of the pedestal 1128. The transmission lines 1170, 1171 may be a metal sleeve, such as a conductive cylinder, connected to the metal mesh 1120. The transmission lines 1170, 1171 are disposed between the RF power lead 412 and the heater anode 451 and cathode 450. The metal sleeve, i.e., transmission lines 1170, 1171, may surround the RF power lead 412 and prevent the RF power lead 412 from coupling with the heater anode 451 and cathode 450 or forming parasitic plasma adjacent the stem 126. RF energy is contained by both the metal mesh 1020 and the transmission lines 1070, 1071. Again, the length of the transmission line can be used to adjust the voltage standing wave ratio and/or the potential at the substrate while preventing parasitic plasma. Additionally, space is made available for heater 400 controller wiring.

Embodiments disclosed herein disclose method and apparatus to confine the RF plasma above a substrate in a processing chamber, such as a PECVD chamber. The apparatus includes a heater pedestal and its RF shield configuration and RF returning loop which allows an optimized RF performance and RF consistency. In some embodiments, the RF current flows from the showerhead top electrode to the heater bottom electrode through the plasma wherein the bottom electrode is coupled to a shortened nickel RF rod to complete the RF circuit and return the RF back in the inner chamber wall. The techniques disclosed for shortening the RF ground path, such as the short RF rod, conductive coating, plasma shield, substantially prevent RF power loss. Additionally, the techniques disclosed forms a lower bottom electrode potential preventing a bottom chamber light-up and parasitic plasma generation. Therefore, method and apparatus confine the plasma between the faceplate and the substrate, eliminating bottom parasitic plasma.

While the foregoing is directed to embodiments of the disclosure, other and further embodiments of the disclosure may be devised without departing from the basic scope thereof, and the scope thereof is determined by the claims that follow.

What is claimed is:

1. A substrate support pedestal comprising:
a ceramic body having a top surface and a bottom surface;
a stem coupled to the bottom surface of the ceramic body;
a top electrode disposed within the ceramic body;
a conductive rod disposed through the stem and coupled to the top electrode;
a plurality of heater elements disposed within the ceramic body below the top electrode; and
a ground mesh disposed within the ceramic body below the plurality of heater elements and above the bottom surface of the ceramic body.

2. The substrate support pedestal of claim 1, further comprising:
a ground tube disposed through the stem coupled to the ground mesh, the ground tube having an inner hollow portion.

3. The substrate support pedestal of claim 2, wherein the conductive rod is disposed through the inner hollow portion of the ground tube.

4. The substrate support pedestal of claim 2, further comprising:
heater power supply lines coupled to the heater elements, wherein the heater power lines are disposed through the stem.

5. The substrate support pedestal of claim 4, wherein the heater power supply lines are disposed through the inner hollow portion of the ground tube.

6. The substrate support pedestal of claim 4, wherein the heater power supply lines are configured to supply power to at the plurality of heater elements comprising at least a central heater, an intermediary heater, and one or more outer heaters.

7. The substrate support pedestal of claim 4, wherein the conductive rod is an RF tube having a cylindrical shape.

8. The substrate support pedestal of claim 7, wherein the heater power supply lines are disposed inside the RF tube.

9. The substrate support pedestal of claim 1, wherein the conductive rod has a capacitor disposed at an end opposite the top electrode.

10. The substrate support pedestal of claim 9, wherein the conductive rod is coupled to a ground through the capacitor, wherein the capacitor is configured for varying an impedance of the conductive rod.

11. A semiconductor processing chamber, comprising:
a chamber body having sidewalls, a lid and a bottom, wherein the sidewalls, lid and bottom define an interior processing environment;
a showerhead assembly having a faceplate, the faceplate provides a cathode to an RF source; and
a pedestal disposed in the interior processing environment, the pedestal comprising:
a stem;
a body comprising a ceramic material having a top surface and a bottom surface, wherein the bottom surface is coupled to the stem;
a top electrode encapsulated within the body disposed adjacent the top surface;
a center electrode disposed through the stem and coupled to the top electrode;
a plurality of heater elements encapsulated within the body and coupled to heater electrodes disposed through the stem, the plurality of heater elements disposed below the top electrode;
a bottom mesh encapsulated within the body, the bottom mesh disposed below the plurality of heater elements; and
a plurality of transmission lines coupled to the bottom mesh.

12. The semiconductor processing chamber of claim 11, wherein the plurality of transmission lines are disposed around the center electrode.

13. The semiconductor processing chamber of claim 12, wherein the plurality of transmission lines are disposed around the heater electrodes.

14. The semiconductor processing chamber of claim 12, wherein the heater electrodes are wires or other electrical conductors.

15. The semiconductor processing chamber of claim 12, wherein the center electrode is an RF tube having a cylindrical shape.

16. The semiconductor processing chamber of claim 15, wherein power supply lines for the plurality of heater elements are disposed inside the RF tube.

17. The semiconductor processing chamber of claim 15, power supply lines for the plurality of heater elements are disposed outside the RF tube.

18. The semiconductor processing chamber of claim 11, wherein the center electrode has a capacitor disposed at an end opposite the electrode.

19. The semiconductor processing chamber of claim 18, wherein the center electrode is coupled to a ground rod through the capacitor, wherein the capacitor is configured for varying an impedance of the center electrode.

20. A semiconductor processing chamber, comprising:
a body having sidewalls, a lid and a bottom, wherein the sidewalls, lid and bottom define an interior processing environment;
a showerhead assembly having a faceplate; and
a pedestal disposed in the interior processing environment, the pedestal comprising:
a stem;
a body comprising a ceramic material having a top surface and a bottom surface, wherein the bottom surface is coupled to the stem;
a top electrode encapsulated within the body disposed adjacent the top surface;
a center electrode disposed through the stem and coupled to the top electrode;
a plurality of heater elements encapsulated within the body and coupled to heater electrodes disposed through the stem, the plurality of heater elements disposed below the top electrode;
a bottom mesh encapsulated within the body, the bottom mesh disposed below the plurality of heater elements;
a plurality of transmission lines disposed in the stem and coupled to the bottom mesh, each transmission line of the plurality of transmission lines disposed radially outward of the center electrode.
